(19) United States
(12) Patent Application Publication
(10) Pub. No.: US 2022/0365615 A1
(43) Pub. Date: Nov. 17, 2022

(54) ON-CELL TOUCH DISPLAY AND PREPARING METHOD THEREOF

(71) Applicant: Cambrios Film Solutions Corporation, Tortola (VG)

(72) Inventors: Chung-Chin Hsiao, Hsinchu County (TW); Siou-Cheng Lien, Miaoli County (TW); Chia-Yang Tsai, New Taipei City (TW); Chi-Fan Hsiao, Taoyuan City (TW)

(21) Appl. No.: 17/319,132

(22) Filed: May 13, 2021

(51) Int. Cl. G06F 3/041; H01L 27/32

(52) U.S. Cl. CPC G06F 3/041; H01L 27/323; G06F 2203/04103

(57) ABSTRACT

An on-cell touch display and a preparing method thereof are provided. The on-cell touch display includes a display panel and a touch sensor disposed on the display panel. The touch sensor includes a first conductive thin film, which is formed on the display panel; an insulating layer, which is formed on the first conductive thin film; a second conductive thin film, which is formed on the insulating layer; and a protective film, which is formed on the second conductive thin film; wherein the non-uniformity value of the first conductive thin film and the second conductive thin film is less than 15% respectively.

### BACKGROUND OF THE DISCLOSURE

### 1. Field of the Disclosure

The present disclosure relates to an on-cell touch display and a preparing method thereof; particularly, the present disclosure relates to an on-cell touch organic light-emitting diode (OLED) display and preparing method thereof.

### 2. Description of Related Art

Recently, the application of touch display devices is becoming more extensive, and many electrical appliances are equipped with touch display for providing the functions of direct operation or issuing commands for making those electronic appliances user-friendly. Therefore, the demand for touch display is increasing.

Today's silver nanowire touch display is an out-cell touch display. However, in the integration of the out-cell silver nanowire touch panel, a laminating process is required to adhere the touch panel to the display. The additional laminating process includes the steps of repeatedly removing a protective film or a releasing film and coating an adhesive, which is relatively complicated, time-consuming, and expensive. In addition to affecting the manufacturing yield, the overall stacking thickness after modularization will also be relatively thick, and a bending property of the out-cell silver nanowire touch panel will be affected.

However, the process for preparing the silver nanowire touch panel includes high-temperature baking steps; therefore, if a silver nanowire thin film is applied to an on-cell touch display, especially applied to an organic light-emitting diode (OLED) display, the heat generated from the preparing process may cause damage to the OLED.

### SUMMARY OF THE DISCLOSURE

The present disclosure provides a novel on-cell touch panel, which includes a display panel and a touch sensor being disposed on the display panel, wherein the touch sensor includes a first conductive thin film disposed on the display panel; an insulating layer disposed on the first conductive thin film; a second conductive thin film disposed on the insulating layer, and a protective film disposed on the second conductive thin film; wherein a non-uniformity value of the first conductive thin film and a non-uniformity value the second conductive thin film are less than 15% respectively.

In one embodiment, the first conductive thin film and the second conductive thin film are made of silver nanowires.

In one embodiment, a surface resistance value of the first conductive thin film and a surface resistance value of the second conductive thin film are 50-100 ohm/sq respectively.

In one embodiment, the display panel is selected from the group consisting of a free plasma display panel (PDP), a liquid crystal display panel (LCD), a thin film transistor liquid crystal display panel (TFT-LCD), an organic light-emitting diode display panel (OLED), a light-emitting diode display panel (LED), an electricity electroluminescent display panel (ELD), a surface conduction electron emission display panel (SED), and a field emission display panel (FED).

In one embodiment, the display is an organic light-emitting diode display panel.

The present disclosure further provides a preparing method of an on-cell touch display, which includes the steps of (A) providing a display panel; (B) forming a first conductive material layer on the display panel; (C) patterning the first conductive material layer to form a first conductive thin film; (D) coating an insulating material on the first conductive thin film and patterning the insulating material to form an insulating layer; (E) forming a second conductive material layer on the insulating layer; (F) patterning the second conductive material layer to form a second conductive thin film; and (G) forming a protective film on the second conductive thin film for accomplishing the on-cell touch display; wherein a process temperature of step (B) and step (G) is lower than 100° C. and a non-uniformity value of the first conductive thin film and a non-uniformity value of the second conductive thin film are less than 15% respectively.

In one embodiment, a surface resistance value of the first conductive material layer in step (B) and a surface resistance value of the second conductive material layer in step (E) are 50-100 ohm/sq respectively.

In one embodiment, the first conductive material layer in step (B) and the second conductive material layer in step (E) are made of silver nanowires.

In one embodiment, step (B) of the preparing method includes the steps of (B-1) forming a silver nanowire layer including the silver nanowires on the display panel; and (B-2) performing a low-temperature baking process, wherein a baking temperature of the low-temperature baking process is lower than 100° C. and a baking time of the low-temperature baking process is more than 5 minutes to form the first conductive material layer.

In one embodiment, step (B) further includes, between step (B-1) and step (B-2), a step of (B-1′) forming a hard-coating layer on the silver nanowire layer.

In one embodiment, step (E) of the preparing method includes steps of (E-1) forming a silver nanowire layer including the silver nanowires on the insulating layer; and (E-2) performing a low-temperature baking process, wherein a baking temperature of the low-temperature baking process is lower than 100° C. and a baking time of the low-temperature baking process is more than 5 minutes to form the second conductive material layer.

In one embodiment, step (E) further includes, between step (E-1) and step (E-2), a step of (E-1′) forming a hard-coating layer on the silver nanowire layer.

In one embodiment, the display panel in step (A) is selected from a group consisting of a free plasma display panel (PDP), a liquid crystal display panel (LCD), a thin film transistor liquid crystal display panel (TFT-LCD), an organic light-emitting diode display panel (OLED), a light-emitting diode display panel (LED), an electricity electroluminescent display panel (ELD), a surface conduction electron emission display panel (SED), and a field emission display panel (FED).

In one embodiment, the display panel in step (A) is an organic light-emitting diode display panel.

It should be noted that the term “on” in the specification may be used herein to describe the relative positions between components. For example, a first element disposed “on” a second element includes embodiments in which the first element is formed in direct contact with the second element, and may also include embodiments in which additional components may be formed between the first element and the second element.

Furthermore, the terms “first”, “second”, “third”, and the like in the specification may be used herein for ease of description and are not related to the numbers or the orders. For example, “first conductive thin film” and “second conductive thin film” can both be realized as “conductive thin film”.

In the art of the touch sensor, the on-cell touch sensor can be laminated directly on the display panel; therefore, a thinner and lighter touch display can be realized by omitting the optical adhesive and substrate of the touch sensor. The low-temperature preparing process provided by the present disclosure can make sure that the temperature during the preparing process does not affect the performance of the display panel, especially the performance of the OLED, and prepare a touch display with high stability.

### BRIEF DESCRIPTION OF THE DRAWINGS

FIG. 1 is a preparation flow chart of one embodiment of the on-cell touch display of the present disclosure;

FIG. 2 is a sectional view of the OLED of one embodiment of the present disclosure;

FIG. 3 is a sectional view of forming the first conductive material layer of one embodiment of the present disclosure;

FIG. 4 is a sectional view of patterning the photoresist layer of one embodiment of the present disclosure;

FIG. 5 is a sectional view of forming the first conductive thin film of one embodiment of the present disclosure;

FIG. 6 is a sectional view of patterning the insulating layer of one embodiment of the present disclosure;

FIG. 7 is a sectional view of forming the second conductive thin film of one embodiment of the present disclosure; and

FIG. 8 is a sectional view of the on-cell touch display of one embodiment of the present disclosure.

### DETAILED DESCRIPTION OF THE PREFERRED EMBODIMENT

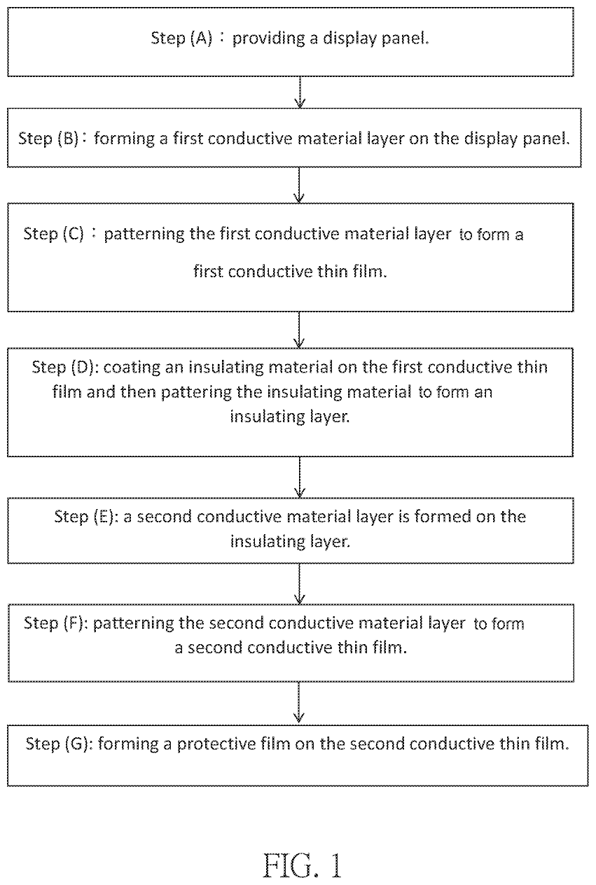

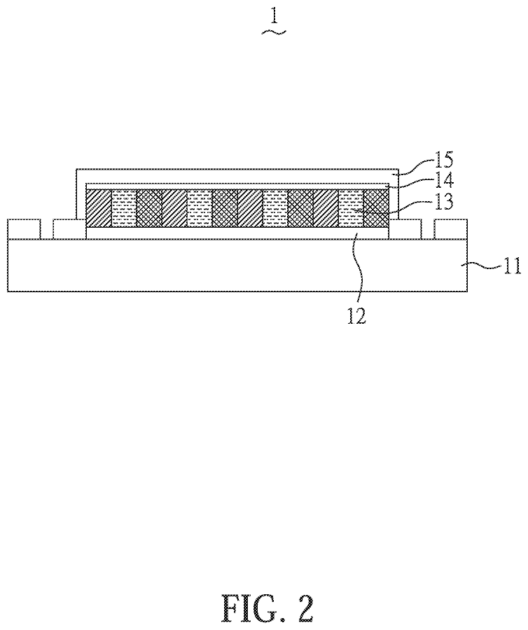

First, a preparing method for preparing an on-cell touch display 1000 of one embodiment of the present disclosure includes the following steps. Please refer to the preparation flow chart illustrated in FIG. 1 and the structural diagrams illustrated in FIG. 2 to FIG. 8.

Step (A): providing a display panel 1. In the present embodiment, the display panel 1 is an OLED panel, which is shown in FIG. 2. The OLED panel includes a substrate 11, a first electrode layer 12, an organic electroluminescent material layer 13, a second electrode layer 14, and a protective film 15. However, in other embodiments, the display panel 1 is not limited to an OLED panel and can be other types of displays that are known in the art.

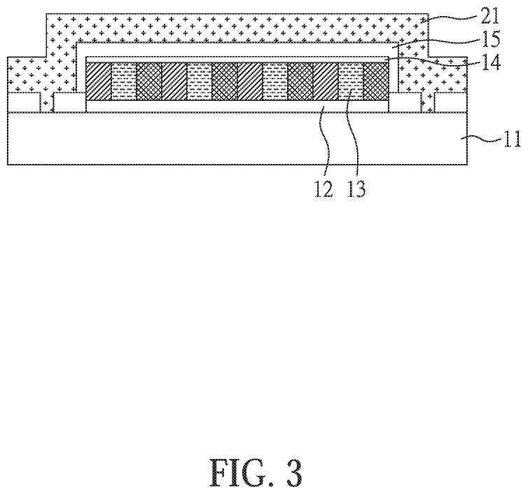

Step (B): forming a first conductive material layer 21 on the display panel 1 as illustrated in FIG. 3. In the present embodiment, the first conductive material layer 21 includes silver nanowires. In detail, step (B) includes a step (B-1): forming a silver nanowire layer (not shown in figures) on the protective film 15 of the display panel 1 via a spin coating method; step (B-1′): forming a hard-coating layer (not shown in figures) on the silver nanowire layer; and step (B-2): performing a low-temperature baking process with a baking temperature lower than 100° C. and a baking time longer than 5 minutes to obtain the first conductive material layer 21. In other embodiments, step (B-1′) can be omitted; that is, the first conductive material layer 21 is only composed of silver nanowires.

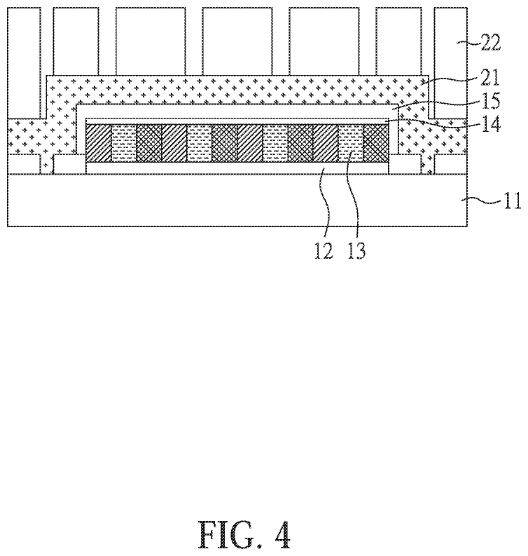

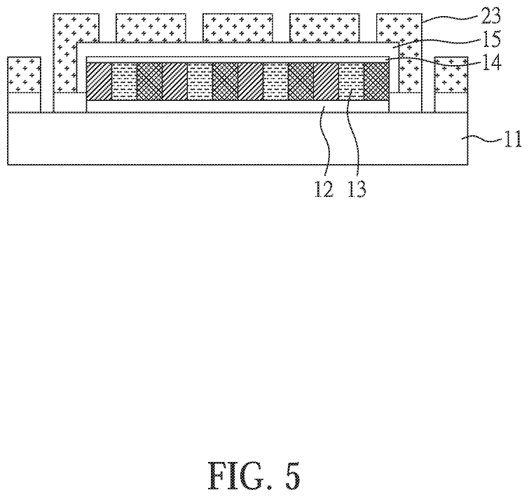

Step (C): patterning the first conductive material layer 21 to form a first conductive thin film 23. In detail, step (C) includes step (C-1): forming a photoresist layer 22 on the first conductive material layer 21 and then patterning the photoresist layer 22 via photolithography to form an electrode pattern shown in FIG. 4; step (C-2): removing part of the first conductive material layer 21 which is not protected by the patterned photoresist layer 22 via etching; and step (C-3): removing the patterned photoresist layer 22 to expose the first conductive thin film 23 as illustrated in FIG. 5. In the present embodiment, the etching process in step (C-2) can be performed by dry-etching or wet-etching; however, in other embodiments, part of the first conductive material layer 21 not covered by the patterned photoresist layer 22 can be removed by non-etching methods, such as a development method or a lift-off method.

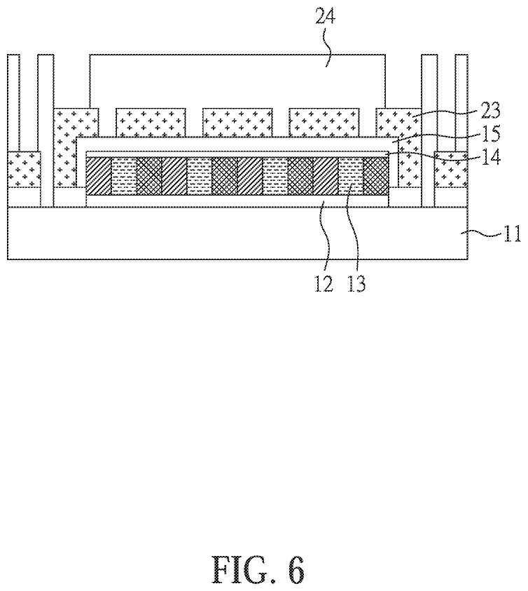

Step (D): coating an insulating material on the first conductive thin film 23 and then patterning the insulating material to form an insulating layer 24. As shown in FIG. 6, the insulating layer 24 is formed by patterning the insulating material through photolithography.

Step (E): a second conductive material layer (not shown in figures) is formed on the insulating layer 24. Similar to step (B), step (E) includes step (E-1): forming a silver nanowire layer (not shown in figures) on the insulating layer 24 via a spin coating method; step (E-1′): forming a hard-coating layer (not shown in figures) on the silver nanowire layer; and step (E-2): performing a low-temperature baking process with a baking temperature lower than 100° C. and a baking time longer than 5 minutes to obtain the second conductive material layer. Similarly, in other embodiments, step (E-1′) can be omitted; that is, the second conductive material layer is only composed of silver nanowires.

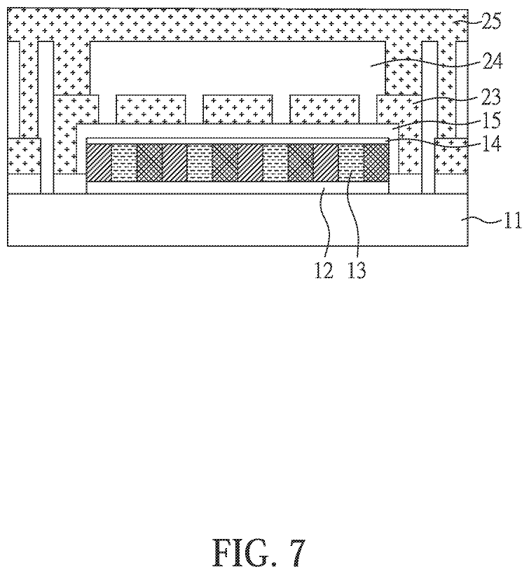

Step (F): patterning the second conductive material layer to form a second conductive thin film 25. Similar to step (C), step (F) includes step (F-1): forming a photoresist layer on the second conductive material layer and then patterning the photoresist layer via photolithography to form an electrode pattern; step (F-2) removing part of the second conductive material layer which is not protected by the patterned photoresist layer via etching; and step (F-3): removing the patterned photoresist layer to form the second conductive thin film 25 as illustrated in FIG. 7. In the present embodiment, the etching process in step (F-2) can be performed by dry-etching or wet-etching; however, in other embodiments, part of the second conductive material layer not covered by the patterned photoresist layer can be removed by non-etching methods, such as a development method or a lift-off method.

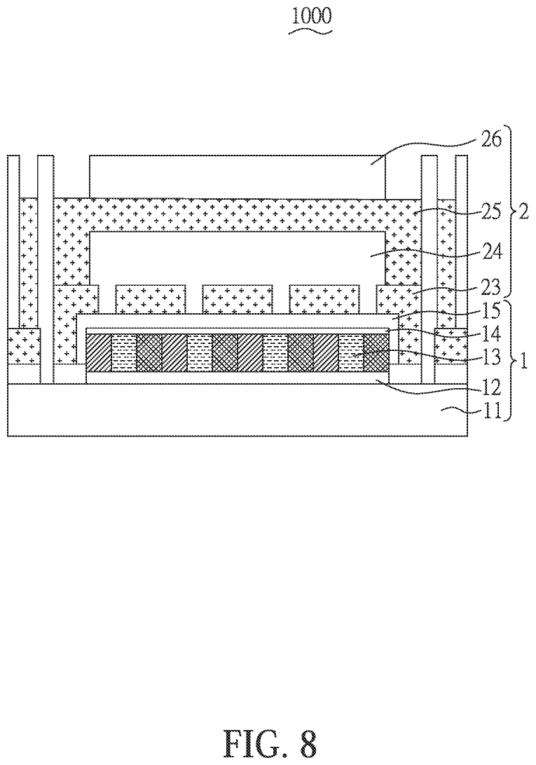

At last, step (G): forming a protective film 26 on the second conductive thin film 25. As illustrated in FIG. 8, the on-cell touch display 1000 is accomplished (i.e., formed).

The on-cell touch display 1000 prepared by the abovementioned preparing method and illustrated in FIG. 8 includes a display panel 1 and a touch sensor 2, wherein the touch sensor 2 is disposed on the display panel 1. The touch sensor 2 includes the first conductive thin film 23 contacting with the display panel 1, the insulating layer 24 disposed on the first conductive thin film 23, the second conductive thin film 25 disposed on the insulating layer 24, and the protective film 26 disposed on the second conductive thin film 25.

### Evaluation of Surface Resistance Value and Uniformity Value

In the present evaluation, the silver nanowires were spin-coated onto a substrate and then baked with the baking temperature lower than 100° C. and 0.5, 1, 2, 5, 10, 20, 30 minutes of baking time for preparing the conductive thin films of experimental examples and comparative examples. A surface resistance value and uniformity value of the silver nanowires of the experimental examples and comparative examples were then tested.

The surface resistance values (Rs) of each example were tested through a non-contact surface resistance measurement system utilizing eddy current induction, and the test results are shown in Table 1.

The surface resistance (R) of 9 points out of a 15 cm×15 cm sheet sample were tested. The non-uniformity (Non-U) (%) of each sample was calculated by the following formula:

Non-uniformity (%)=Rsₘₐₓ−Rsₘᵢₙ/2×Rs_{average}

The conductive thin films with a non-uniformity value lower than 10% have great uniformity.

TABLE 1

| | Comparative | Comparative | Comparative | | | | |
|---|---|---|---|---|---|---|---|
| | Example 1 | Example 2 | Example 3 | Example 1 | Example 2 | Example 3 | Example 4 |
| Baking time | 0.5 | 1 | 2 | 5 | 10 | 20 | 30 |
| (min) | | | | | | | |
| Rs | 472.86 | 275.79 | 225.82 | 88.87 | 84.03 | 83.49 | 77.96 |
| (ohm/sq) | | | | | | | |
| Non-U | 22.03 | 25.52 | 30.71 | 10.71 | 7.42 | 6.42 | 6.78 |
| (%) | | | | | | | |

| | | |
|---|---|---|
| Judgment | Fail | Pass |

According to the results shown in Table 1, the surface resistances and the non-uniformity of the conductive thin film of Comparative Examples 1 to 3 prepared with 0.5, 1, and 5 minutes of baking time are too high, wherein the higher non-uniformity represents the lower uniformity. However, according to the test results of Examples 1 to 4, with 5, 10, 20, and 30 minutes of baking time, the surface resistance and the non-uniformity of the conductive thin film are significantly decreased. That is, the conductive thin films of Examples 1 to 4 each have excellent conduction and uniformity. Based on the result, the conductive thin films prepared by the baking process with the baking temperature lower than 100° C. and at least 5 minutes of baking time are stably characterized with high uniformity and low surface resistance.

### Evaluation of Line Resistance

The present evaluation evaluated a line resistance of the first conductive thin film 23 and the second conductive thin film 25 for four periods of time during the preparing process of the present disclosure to see if the line resistance of the first conductive thin film 23 or the second conductive thin film 25 was affected after different preparing stages. In detail, step (A) to step (C) of the present preparing method were considered as the first preparing stage (PEP1). The line resistances of five conductive lines (Tx1 to Tx5) of the first conductive thin film 23 in PEP1 were measured. Step (D) to step (E) were considered as the second preparing stage (PEP2) of the present preparing method, wherein the line resistances of five conductive lines (Tx1 to Tx5) of the first conductive thin film 23 in PEP2 were measured. Step (F) for forming the second conductive thin film 25 was considered as the third preparing stage (PEP3) of the present preparing method, wherein the line resistances of five conductive lines (Tx1 to Tx5) of the first conductive thin film 23 and five conductive lines (Rx1 to Rx5) in PEP3 were measured. At last, step (G) for forming the protective film was considered as the fourth preparing stage (PEP4) of the present preparing method, wherein the line resistances of five conductive lines (Tx1 to Tx5) of the first conductive thin film 23 and five conductive lines (Rx1 to Rx5) in PEP4 were measured. The results are shown in Table 2.

TABLE 2

| | Tx1 | Tx2 | Tx3 | Tx4 | Tx5 | Rx1 | Rx2 | Rx3 | Rx4 | Rx5 |
|---|---|---|---|---|---|---|---|---|---|---|
| PEP1 | 1.93 | 1.87 | 1.85 | 1.81 | 1.7 | — | — | — | — | — |
| PEP2 | 1.95 | 1.91 | 1.91 | 1.86 | 1.72 | — | — | — | — | — |
| PEP3 | 1.95 | 1.89 | 1.84 | 1.88 | 1.72 | 1.05 | 1.13 | 1.16 | 1.18 | 1.16 |
| PEP4 | 1.93 | 1.91 | 1.93 | 1.87 | 1.81 | 1.08 | 1.17 | 1.17 | 1.19 | 1.19 |

(unit: kΩ)

According to the results shown in Table 2, it should be noted that the line resistances of the first conductive thin film 23 and the second conductive thin film 25 were all very stable in every stage of the preparing process (RI<10%). Therefore, during the preparing process of the on-cell touch display provided by the present disclosure, steps of exposure, development, etching, and patterning may be effectively and stably conducted on the OLED display for accomplishing the on-cell touch display 1000.

In summary, in the preparing process for preparing the on-cell touch display 1000 provided by the present disclosure, each step must be conducted with low temperature; that is, the steps of coating silver nanowires, photoresist, insulating material, and protective film must be conducted with a temperature lower than 100° C. for preventing the effect on OLED caused by the heat generated by the preparing process. Therefore, the first conductive thin film 23 and the second conductive thin film 25 (formed by the silver nanowires) showed excellent low surface resistance (10-80 ohm/sq) and high uniformity (non-U %<10%).

The above disclosure is related to the detailed technical contents and inventive features thereof. People skilled in the art may proceed with a variety of modifications and replacements based on the disclosures and suggestions of the disclosure as described without departing from the characteristics thereof. Nevertheless, although such modifications and replacements are not fully disclosed in the above descriptions, they have substantially been covered in the following claims as appended.

What is claimed is:

1. An on-cell touch display, comprising:
a display panel; and
a touch sensor being disposed on the display panel, comprising:
a first conductive thin film disposed on the display panel;
an insulating layer disposed on the first conductive thin film;
a second conductive thin film disposed on the insulating layer; and
a protective film disposed on the second conductive thin film,
wherein a non-uniformity value of the first conductive thin film and a non-uniformity value of the second conductive thin film are less than 15% respectively.

2. The on-cell touch display of claim 1, wherein the first conductive thin film and the second conductive thin film are made of silver nanowires.

3. The on-cell touch display of claim 2, wherein a surface resistance value of the first conductive thin film and a surface resistance value of the second conductive thin film are 50-100 ohm/sq respectively.

4. The on-cell touch display of claim 1, wherein the display panel is selected from the group consisting of a free plasma display panel (PDP), a liquid crystal display panel (LCD), a thin film transistor liquid crystal display panel (TFT-LCD), an organic light-emitting diode display panel (OLED), a light-emitting diode display panel (LED), an electricity electroluminescent display panel (ELD), a surface conduction electron emission display panel (SED), and a field emission display panel (FED).

5. The on-cell touch display of claim 1, wherein the display panel is an organic light-emitting diode display panel.

6. A preparing method of an on-cell touch display, comprising steps of:
(A) providing a display panel;
(B) forming a first conductive material layer on the display panel;
(C) patterning the first conductive material layer to form a first conductive thin film;
(D) coating an insulating material on the first conductive thin film and patterning the insulating material to form an insulating layer;
(E) forming a second conductive material layer on the insulating layer;
(F) patterning the second conductive material layer to form a second conductive thin film; and
(G) forming a protective film on the second conductive thin film for accomplishing the on-cell touch display,
wherein a process temperature of step (B) and step (G) is lower than 100° C. and a non-uniformity value of the first conductive thin film and a non-uniformity value of the second conductive thin film are less than 15% respectively.

7. The preparing method of claim 6, wherein a surface resistance value of the first conductive material layer in step (B) and a surface resistance value of the second conductive material layer in step (E) are 50-100 ohm/sq respectively.

8. The preparing method of claim 6, wherein the first conductive material layer in step (B) and the second conductive material layer in step (E) are made of silver nanowires.

9. The preparing method of claim 8, wherein step (B) comprises steps of:
(B-1) forming a silver nanowire layer comprising the silver nanowires on the display panel; and
(B-2) performing a low-temperature baking process, wherein a baking temperature of the low-temperature baking process is lower than 100° C. and a baking time of the low-temperature baking process is more than 5 minutes to form the first conductive material layer.

10. The preparing method of claim 9, wherein step (B) further comprises, between step (B-1) and step (B-2), a step of:
(B-1′) forming a hard-coating layer on the silver nanowire layer.

11. The preparing method of claim 8, wherein step (E) comprises steps of:
(E-1) forming a silver nanowire layer comprising the silver nanowires on the insulating layer; and
(E-2) performing a low-temperature baking process, wherein a baking temperature of the low-temperature baking process is lower than 100° C. and a baking time of the low-temperature baking process is more than 5 minutes to form the second conductive material layer.

12. The preparing method of claim 11, wherein step (E) further comprises, between step (E-1) and step (E-2), a step of:
(E-1′) forming a hard-coating layer on the silver nanowire layer.

13. The preparing method of claim 6, wherein the display panel in step (A) is selected from a group consisting of a free plasma display panel (PDP), a liquid crystal display panel (LCD), a thin film transistor liquid crystal display panel (TFT-LCD), an organic light-emitting diode display panel (OLED), a light-emitting diode display panel (LED), an electricity electroluminescent display panel (ELD), a surface conduction electron emission display panel (SED), and a field emission display panel (FED).

14. The preparing method of claim 6, wherein the display panel in step (A) is an organic light-emitting diode display panel.
